(19) United States
(12) Patent Application Publication
(10) Pub. No.: US 2021/0129245 A1
(43) Pub. Date: May 6, 2021

(54) METHOD FOR PRODUCING A COMPONENT WHICH IS CONNECTED TO A SOLDER PREFORM

(71) Applicant: Heraeus Deutschland GmbH & Co. KG, Hanau (DE)

(72) Inventors: Michael Schäfer, Kunzell (DE); Wolfgang Schmitt, Roadgau (DE); Nadja Pelshaw, Rodenbach (DE)

(21) Appl. No.: 16/629,496

(22) PCT Filed: Oct. 29, 2018
(86) PCT No.: PCT/EP2018/079558

§ 371 Date: Jan. 8, 2020

(30) Foreign Application Priority Data
Dec. 13, 2017 (EP) 17207043.5

(51) Int. Cl. B23K 1/20; H01L 23/00; B23K 35/26; B23K 35/02; C22C 13/00

(52) U.S. Cl. CPC B23K 1/20; B23K 2101/40; H01L 24/83; B23K 35/262; B23K 35/0233; C22C 13/00; H01L 2224/29211; H01L 2224/29247; H01L 2224/29239; H01L 2224/29209; H01L 2224/29263; H01L 2224/29255; H01L 2224/29216; H01L 2224/29213; H01L 2224/2922; H01L 2224/83815; H01L 2924/014; H01L 2924/0105; H01L 2924/01029; H01L 2924/01047; H01L 2924/01049; H01L 2924/01032; H01L 2924/01028; H01L 2924/01082; H01L 2924/01083; H01L 2924/01051; H01L 24/29

(57) ABSTRACT

A method for producing a component bonded to a solder preform, comprising the following steps:
(1) providing a component having at least one contact surface, and a free solder preform,
(2) producing an assembly of the component and the solder preform, which is not yet bonded to said component, by bringing a contact surface, or the sole contact surface, of the component into contact with a contact surface of the free solder preform, and
(3) forming the component bonded to the solder preform by hot pressing the assembly produced in step (2) at a temperature that is 10 to 40% lower than the melting temperature of the soldering metal of the solder preform, expressed in ° C., and with a combination of pressing force and pressing duration that will effect a reduction of 10% in the original thickness of the originally free solder preform.

The invention relates to a method for producing a component bonded to a solder preform.

As used herein, the term “component bonded to a solder preform” means that a solder preform and component adhere to one another with a shear strength of >0.1 MPa; in other words, their adhesion to one another is characterized by a shear strength of >0.1 MPa. The shear strength can be determined using a conventional shear tester. U.S. Pat. No. 4,659,006 discloses bonding a substrate to a free solder preform by hot pressing as a substep of a method for producing a hard-soldered joint between a semiconductor chip and a substrate. When bonding the substrate to the free solder preform, the substrate and solder preform are first brought into contact with one another and are then heated together to a temperature that is below the melting temperature of the solder preform. While this temperature is maintained, pressing force is applied to the solder preform. The original thickness of the solder preform is thereby reduced by at least 40%. The resulting assembly of substrate equipped with solder depot is then hard-soldered to a semiconductor chip in a conventional manner.

Distinction is deliberately made herein between soft-soldering and hard-soldering of components. While soft-soldering and hard-soldering both produce a thermally conductive, electrically conductive, and mechanical bonding of components, the difference between soft-soldering and hard-soldering is that during the formation of a hard-soldered joint, in contrast to the formation of a soft-soldered joint, the soldering metal is melted and re-solidified between the components, in other words, it is heated above its melting temperature and then cooled below its solidification temperature.

The applicant has now established that, surprisingly, it is possible to bond a component to a free solder preform using a procedure substantially similar to the procedure known from U.S. Pat. No. 4,659,006, but under milder hot-pressing conditions.

The invention relates to a method for producing a component bonded to a solder preform. Said method comprises the following steps:

(1) providing a component having at least one contact surface, and a free solder preform,

(2) producing an assembly of the component and the solder preform, which is not yet bonded to said component, by bringing a contact surface, or the sole contact surface, of the component into contact with a contact surface of the free solder preform, and

(3) forming the component bonded to the solder preform by hot pressing the assembly produced in step (2) at a temperature that is 10 to 40% lower than the melting temperature of the soldering metal of the solder preform, expressed in ° C., and with a combination of pressing force and pressing duration that will effect a reduction of 10% in the original thickness of the originally free solder preform.

In step (1) of the method, a component having a single contact surface or multiple contact surfaces is provided.

In the context of the invention, the term component preferably comprises individual parts. These individual parts preferably cannot be further dismantled.

The contact surface(s) of components are generally metallic, for example in the form of a metallization layer. The metal of a component or of its contact surface(s) may be pure metal or an alloy composed of >50% to <100% by weight of the metal and accordingly >0% to <50% by weight at least one other metal. Examples of the pure metal or the main metal of the alloy are tin, copper, silver, gold, nickel, palladium, and platinum, in particular tin, copper, silver, gold, palladium, and platinum.

The size of the contact surface of the component used in step (2) to produce the assembly may range, for example, from 1 to 3000 mm², in particular from >10 to 1000 mm², especially from 15 to 500 mm².

A component in the context of the invention may be a substrate or an active or passive component. In particular, it is a type of component used in electronics.

Examples of substrates are IMS substrates (insulated metal substrates), DCB (direct copper bonded) substrates, AMB (active metal braze) substrates, ceramic substrates, PCBs (printed circuit boards), and lead frames.

Examples of active components are diodes, LEDs (light-emitting diodes), dies (semiconductor chips), IGBTs (insulated-gate bipolar transistors), ICs (integrated circuits), and MOSFETs (metal-oxide-semiconductor field-effect transistors).

Examples of passive components are sensors, ground plates, heat sinks, resistors, capacitors, transformers, chokes, and coils.

In addition to the component having at least one contact surface, a free, i.e., discrete solder preform is provided in step (1) of the method.

In the context of the invention, a free solder preform is, in particular, soldering metal in the form of a flat molded part, for example metal soldering foil, metal soldering tape, or a metal soldering disk. Such free solder preforms have discrete contact surfaces, i.e., separate and distinguishable contact surfaces, in particular two contact surfaces located on opposite sides. The contact surfaces may have any shape, for example, round, hexagonal, triangular, or preferably rectangular. Their size and shape preferably correspond to the contact surface of the component. The thickness of the free solder preform may range, for example, from 10 to 500 μm or from 50 to 300 μm.

The soldering metal (solder) of the solder preform is generally indium, indium alloys or, in particular, tin or tin-rich alloys. Examples of tin-rich alloys are those having a tin content ranging from 90 to 99.5% by weight, for example. Examples of alloying metals are copper, silver, indium, germanium, nickel, lead, bismuth, and antimony. The alloys may be leaded or lead-free. Lead-free alloys may be selected, for example, from the group consisting of SnAg, SnBi, SnSb, SnAgCu, SnCu, SnSb, InSnCd, InBiSn, InSn, BiSnAg, and SnAgCuBiSbNi. Leaded alloys may be selected, for example, from the group comprising SnPb and SnPbAg. The melting temperature of the soldering metal may lie within a range, for example, of 140° C. to 380° C., in particular 170° C. to 300° C.

In step (2) of the method according to the invention, an assembly composed of the component and the solder preform is produced, in which the component and solder preform are not yet bonded to one another. In said assembly, the solder preform is merely positioned, but it is no longer in its original, free position. For this purpose, a contact surface of the free solder preform is brought into contact with a contact surface, or with the sole contact surface, of the component, for example by positioning the free solder preform with one of its contact surfaces facing the relevant contact surface of the component. In general, positioning the free solder preform means placing said preform on the component, or vice versa, or fitting the component with the free solder preform, or vice versa.

In one embodiment, a fixing agent composed of a fixing agent compound may be used between the two contact surfaces to be brought into contact with one another, or may be applied to one or both contact surfaces before they are brought into contact with one another.

In step (3) of the method according to the invention, the assembly produced in step (2) is subjected to hot pressing, in which component and positioned solder preform are bonded to form a component bonded to a solder preform. The component bonded to the solder preform has an outwardly facing soldering metal contact surface. The bonded solder preform is what is known as a solder depot.

The tool used may be a conventional hot press, for example. The hot pressing is carried out at a temperature that is 10 to 40% lower than the melting temperature, expressed in ° C., of the soldering metal of the solder preform, and under the influence of a combination of pressing force and pressing duration that will effect a reduction of 10% in the original thickness of the originally free solder preform (i.e., the solder preform in its original free state). Specifically, the melting temperature of the soldering metal may lie within a range of 140° C. to 380° C., for example, in which case the temperature during hot pressing may range from 84° C. to 342° C., for example. Depending upon the original thickness of the originally free solder preform, said reduction in thickness of 10% may range, for example, from 0 to 50 μm.

The combination of pressing force and pressing duration, which, at a temperature that is 10 to 40% lower than the melting temperature, expressed in ° C., of the soldering metal of the solder preform, causes a reduction in the original thickness of the originally free solder preform of 10%, may lie within a range, for example, of 10 to 200 MPa pressing force and 1 second to 5 minutes pressing duration. The higher the selected pressing force, the shorter the selected pressing time can be, and vice versa.

The method according to the invention operates with significantly milder hot-pressing conditions than those disclosed in the aforementioned U.S. Pat. No. 4,659,006. And a sufficiently strong bond between component and originally free solder preform is thereby achieved.

As mentioned above, the method according to the invention has various advantages, both in terms of the actual implementation of the method and in terms of the direct product of the method in the form of the component bonded to the originally free solder preform.

The method according to the invention can be carried out using a hot press of relatively simple design.

The method according to the invention can also be carried out using components that are more pressure-sensitive than those disclosed in the aforementioned U.S. Pat. No. 4,659,006.

In embodiments, the method according to the invention and/or the hot pressing can even be carried out in a normal ambient atmosphere, i.e., in air, without any special precautions, i.e., it is not necessary to work under inert gas or in a reducing atmosphere, such as an inert gas/hydrogen atmosphere, for example.

The solder preform bonded to the component in the method according to the invention is characterized not only by a thickness that is 10% thinner than the original thickness of the originally free solder preform, but also by a shape and a surface area that are substantially unchanged from the original shape and surface area once hot pressing has been completed. Thus, essentially no bulges form along the outer edges of the solder preform bonded to the component in the method according to the invention, an advantageous fact in light of the increasing miniaturization in the electronics sector and the concomitant increase in component density. For example, free solder preforms that are originally rectangular remain substantially rectangular once they have been bonded to the component, with substantially straight, i.e., substantially non-curved, outer edges. The term “substantially” used multiple times in this paragraph refers to the impression when viewed with the naked eye.

The component bonded to a solder preform as produced in the method according to the invention can be used to bond a further component thereto, or in other words, to create a fixed sandwich assembly from the first component provided in step (1) and an additional component, with solder therebetween. For this purpose, the outwardly facing soldering metal contact surface of the component bonded to a solder preform, produced by the method according to the invention, can be brought into contact with a contact surface, or with the sole contact surface, of the additional component to be bonded thereto, and subsequently bonded.

The term “fixed sandwich assembly” used herein means that the components adhere to one another with a shear strength of >0.1 MPa, imparted via the solder located therebetween; in other words, their adhesion to one another is characterized by a shear strength of >0.1 MPa. The shear strength can be determined using a conventional shear tester.

The first component provided in step (1) and the additional component to be bonded thereto may be of the same type, i.e., both may be substrates, for example, or both may be active or passive components, or they may be one active and one passive component. However, it is also possible for one component to be a substrate and the other component an active or passive component, or vice versa. For example, the following cases may be distinguished:

| First component: | Additional component: |
|---|---|
| Substrate | Substrate |
| Active component | Passive component |
| Passive component | Active component |
| Active component | Active component |
| Passive component | Passive component |
| Substrate | Active component |
| Substrate | Passive component |
| Passive component | Substrate |
| Active component | Substrate |

There are two possible options for producing the bond between the two components. For one, a traditional hard-soldering process can be carried out; alternatively, the method may proceed similarly to the aforementioned hot-pressing process.

In the traditional hot-soldering alternative, which is known to a person skilled in the art and therefore requires no further explanation, the method according to the invention is followed by the following additional steps:

(4) producing a sandwich assembly composed of solder preform bonded to the component and an additional component to be bonded thereto by bringing the outwardly facing soldering metal contact surface of the solder preform that is bonded to the component into contact with a contact surface, or with the sole contact surface, of the additional component,

(5) heating the sandwich assembly to a temperature above the melting temperature of the soldering metal of the solder preform, and

(6) cooling the sandwich assembly below the solidification temperature of the molten soldering metal located between the components, thereby forming a hard-soldered joint between the components.

In step (4), the outwardly facing soldering metal contact surface of the solder preform bonded to the component in step (3) is brought into contact with a contact surface, or with the sole contact surface, of the additional component, for example by positioning the additional component with the relevant contact surface facing the soldering metal contact surface. In general, positioning means placing the additional component on the assembly produced in step (3), or vice versa, or fitting the assembly produced in step (3) with the additional component, or vice versa.

Step (5) involves a hard-soldering process.

Upon completion of step (6), a fixed sandwich assembly is obtained, composed of the component originally provided in step (1) and the additional component provided in step (4), with solder producing a thermally conductive, electrically conductive, and mechanical bond therebetween.

In the other alternative of hot pressing, in contrast, the following additional steps follow the method according to the invention:

(4′) producing a sandwich assembly composed of solder preform bonded to the component and an additional component to be bonded thereto by bringing the outwardly facing soldering metal contact surface of the solder preform that is bonded to the component into contact with a contact surface, or with the sole contact surface, of the additional component, and

(5′) hot pressing the sandwich assembly produced in step (4′) at a temperature that is 10 to 40% lower than the melting temperature, expressed in ° C., of the soldering metal of the solder preform bonded to the component provided in step (1), thereby forming a soft-soldered joint between the components.

In step (4′), the outwardly facing soldering metal contact surface of the solder preform bonded to the component is brought into contact with a contact surface, or with the sole contact surface, of the additional component, for example by positioning the additional component with the relevant contact surface facing the soldering metal contact surface. In general, positioning means placing the additional component on the assembly produced in step (3), or vice versa, or fitting the assembly produced in step (3) with the additional component, or vice versa.

In step (5′), the sandwich assembly produced in step (4′) is subjected to hot pressing, in which the component bonded to the solder preform is bonded to the additional component. In this case, a soft-soldered joint is formed between the components.

A conventional hot press can be used as the tool. The hot pressing is carried out at a temperature that is 10 to 40% lower than the melting temperature, expressed in ° C., of the soldering metal of the solder preform; reference is made in this regard to the above description. Preferably, the pressing force and the pressing duration, i.e., the combination of the two, are within a range that will effect a reduction of 10% in the thickness of the bonded solder preform (i.e., in the state after completion of step (3)); in that case, the pressing force may be within a range of 10 to 200 MPa and the pressing duration may be within a range of 1 second to 5 minutes, for example. The higher the selected pressing force, the shorter the selected pressing time can be, and vice versa.

In embodiments, step (5′) can be carried out in a normal ambient atmosphere, i.e., in air, without taking special precautions, i.e., it is not necessary to work under inert gas or in a reducing atmosphere, such as an inert gas/hydrogen atmosphere, for example.

Upon completion of step (5′), a sturdy sandwich assembly is obtained from the component originally provided in step (1) and the additional component provided in step (4′), with solder producing a thermally conductive, electrically conductive, and mechanical bond therebetween.

### INVENTIVE EXAMPLE 1

A solder preform (Sn3.5Ag; melting temperature 221° C., 9 mm×9 mm×0.20 mm) was placed centered on the copper surface of a DCB substrate (alumina ceramic, 25 mm×25 mm×380 μm, equipped on the square surfaces of both sides with 300 μm copper), and the assembly thus created was placed between the two plates of a hot press (Sinterstar Innovate F-XL, Boschmann), preheated to 150° C. For a period of 60 seconds, a pressing force of 100 MPa was applied to the sample.

The reduction in thickness of the solder preform was determined using a MITUTOYO ABSOLUTE Digimatic dial gauge.

The shear strength of the sample was measured using a DAGE 4000 plus shear tester from Nordson, at a speed of 0.3 mm/second at 20° C.

In addition, the deformation percentage of the originally square solder preform was determined as a change in the length dimension measured from peak to peak. A deformation percentage of <10% is considered a satisfactory result.

Examples 2 to 14 were carried out similarly to Example 1. The following table shows the effects of pressing temperature, pressing duration, and pressing force applied during hot pressing.

| | | | | Thick- | | |
|---|---|---|---|---|---|---|
| | Pressing | Press- | | ness | | |
| | Temper- | ing | Pressing | Re- | Defor- | Shear |
| | ature | Force | Duration | duction | mation | Strength |
| Example | ( °C.) | (MPa) | (s) | (μm) | (%) | (MPa) |
| 1 (inventive) | 150 | 100 | 60 | 1 | 0 | >0.1 |
| 2 (inventive) | 150 | 100 | 120 | 2 | 4 | >0.1 |
| 3 (inventive) | 150 | 100 | 300 | 4 | 7 | >0.1 |
| 4 (inventive) | 190 | 100 | 60 | 2 | 5 | >0.1 |
| 5 (inventive) | 190 | 100 | 120 | 7 | 8 | >0.1 |
| 6 (not | | | | | | |
| inventive) | 190 | 100 | 300 | 22 | 12 | >0.1 |
| 7 (inventive) | 150 | 50 | 120 | 0 | 0 | >0.1 |
| 8 (not | | | | | | |
| inventive) | 150 | 50 | 60 | 0 | 0 | <0.1 |
| 9 (not | | | | | | |
| inventive) | 150 | 50 | 10 | 0 | 0 | <0.1 |
| 10 (inventive) | 150 | 50 | 300 | 2 | 4 | >0.1 |
| 11 (inventive) | 190 | 50 | 120 | 4 | 6 | >0.1 |
| 12 (inventive) | 190 | 50 | 60 | 1 | 1 | >0.1 |
| 13 (not | 190 | 50 | 10 | 0 | 0 | <0.1 |
| inventive) | | | | | | |
| 14 (inventive) | 190 | 50 | 300 | 6 | 7 | >0.1 |

1. A method for producing a component bonded to a solder preform, comprising the following steps:
(1) providing a component having at least one contact surface, and a free solder preform made of a soldering metal,
(2) producing an assembly of the component and the free solder preform, which is not yet bonded to said component, by bringing a contact surface, or the sole contact surface, of the component into contact with a contact surface of the free solder preform, and
(3) forming the component bonded to the solder preform by hot pressing the assembly produced in step (2) at a temperature that is 10 to 40% lower than the melting temperature of the soldering metal of the solder preform, expressed in ° C., and with a combination of pressing force and pressing duration that will effect a reduction of ≤10% in the original thickness of the originally free solder preform.

2. The method of claim 1, wherein the component is a substrate, an active component, or a passive component.

3. The method of claim 1, wherein the free solder preform is metal soldering foil, metal soldering tape, or a metal soldering disk.

4. The method of claim 1, wherein the free solder preform is 10 to 500 μm thick.

5. The method of claim 1, wherein the melting temperature of the soldering metal of the free solder preform lies within the range of 140° C. to 380° C.

6. The method of claim 1, wherein the melting temperature of the soldering metal of the free solder preform lies within the range of 140° C. to 380° C. and the temperature during hot-pressing lies within the range of 84° C. to 342° C.

7. The method of claim 1, wherein the pressing force lies within the range of 10 to 200 MPa and the pressing duration lies within the range of 1 second to 5 minutes.

8. The method of claim 1, further comprising the following additional steps:
(4) producing a sandwich assembly composed of the solder preform bonded to the component and an additional component to be bonded thereto by bringing the outwardly facing soldering metal contact surface of the solder preform that is bonded to the component into contact with a contact surface, or with the sole contact surface, of the additional component,
(5) heating the sandwich assembly to a temperature above the melting temperature of the soldering metal of the solder preform, and
(6) cooling the sandwich assembly below the solidification temperature of the molten soldering metal located between the components, thereby forming a hard-soldered joint between the components.

9. The method of claim 1, further comprising the following additional steps:
(4′) producing a sandwich assembly composed of solder preform bonded to the component and an additional component to be bonded thereto by bringing the outwardly facing soldering metal contact surface of the solder preform that is bonded to the component into contact with a contact surface, or with the sole contact surface, of the additional component, and
(5′) hot pressing the sandwich assembly produced in step (4′) at a temperature that is 10% to 40% lower than the melting temperature, expressed in ° C., of the soldering metal of the solder preform bonded to the component provided in step (1), thereby forming a soft-soldered joint between the components.

10. The method of claim 9, wherein the combination of pressing force and pressing duration applied during step (5′) lies within a range that will cause a reduction of ≤10% in the thickness of the bonded solder preform.

11. The method of claim 1, wherein the temperature during hot pressing lies within the range of 84° C. to 342° C.

12. The method of claim 1, wherein the soldering metal is a tin-rich alloy.

13. The method of claim 1, wherein the soldering metal is a tin-rich alloy having a tin content ranging from 90 to 99.5% by weight.
